(19) United States
(12) Patent Application Publication
(10) Pub. No.: US 2016/0086790 A1
(43) Pub. Date: Mar. 24, 2016

(54) COMPONENT PREPARATION INSTRUCTION SYSTEM, COMPONENT PREPARATION INSTRUCTION METHOD, AND PORTABLE TERMINAL

(71) Applicant: Panasonic Intellectual Property Management Co., Ltd., Osaka (JP)

(72) Inventors: Yasuhiro MAENISHI, Yamanashi (JP); Atsuto SHIMADA, Yamanashi (JP); Chikashi KONISHI, Osaka (JP); Norihisa YAMASAKI, Yamanashi (JP)

(21) Appl. No.: 14/829,956

(22) Filed: Aug. 19, 2015

(30) Foreign Application Priority Data
Sep. 19, 2014 (JP) 2014-190997

(51) Int. Cl. H01L 21/02; G05B 19/418

(52) U.S. Cl. CPC H01L 21/02; G05B 19/41865; G05B 2219/45031; G05B 2219/31202

(57) ABSTRACT

A component preparation instruction system performs a component preparation instruction for preparing a reel member to be supplied to a component mounting line in an off-line set-up area set outside the component mounting line, in a component mounting system. The component preparation instruction system includes a management section that manages production data including information about the reel members and information about the component mounters to which the reel members is attached, a reading section that reads reel information relating to the reel members, a collating section that collates the reel information read by the reading section with the information about the reel members included in the production data, and an output section that outputs attachment position information for a matching reel member, including information about at least one component mounter to which the matching reel member is to be attached.

### CROSS-REFERENCES TO RELATED APPLICATION(S)

This application is based on and claims priority from Japanese Patent Application No. 2014-190997 filed on Sep. 19, 2014, the entire contents of which are incorporated herein by reference.

### BACKGROUND

1. Field of the Invention

The present invention relates to a component preparation instruction system and a component preparation instruction method for instruction of preparation of a component such as a reel member supplied to a component mounting line, and a portable terminal used in the system and the method.

2. Description of Related Art

A component mounting system that mounts an electronic component onto a board to produce a component-mounted board includes a production floor in which a component mounting line where plural component mounters are arranged is disposed, and a management system having a production management function. The management system has a function of supplying production data indicating information relating to products which are production targets or component information used in production, and is connected to each device that forms the component mounting system through a network.

Component supply to a component mounting line based on a board component mounting line is performed by exchanging a carrier member that holds components in a predetermined configuration and posture, such as a reel member in which a carrier tape is wound and accommodated. Since plural component mounters are arranged in the production floor, and plural types of components are supplied to each component mounter, a component management system for correctly performing matching between a component type and a supply target device when the components are supplied is employed (for example, see JP-A-10-200290 as Patent Document 1). In a related art example disclosed in Patent Document 1, a recognition display of a reel member and a recognition display of a lane where the reel member is mounted are provided to perform matching between the reel member and the lane, in which a matching instruction is automatically given according to a production schedule.

Patent Document 1: JP-A-10-200290

### SUMMARY

There is provided a so-called “off-line set-up method” of performing a component preparation operation such as exchange of a reel member outside a component mounting line. According to the off-line set-up method, since component supply can be performed without stopping the operation of each component mounter of the component mounting line, it is possible to suppress operational loss associated with component distribution, to thereby achieve improvement of productivity.

However, in such an off-line set-up method, when the above-mentioned component management system is applied, the following problems occur. That is, when an actual component mounter is not present in an operation area where an off-line set-up operation is to be performed, accordingly, a lane of a component mounter to which a reel member which is an exchange target is to be mounted cannot be specified. In other words, techniques in the related art such as JP-A-10-200290 mentioned above do not provide a countermeasure for automatic instruction on information matching in a component preparation operation for component supply in the off-line set-up method, and thus, it is difficult to efficiently perform the component preparation operation.

A non-limited object of one or more embodiments of the present invention is to provide a component preparation instruction system and a component preparation instruction method capable of performing automatic instruction on information matching in an off-line set-up operation of performing a component preparation operation outside a component mounting line to efficiently perform the component preparation operation, and a portable terminal used in the system and the method.

A first aspect of the present invention provides a component preparation instruction system that performs a component preparation instruction for preparing a reel member to be supplied to a component mounting line in which a plurality of component mounters is arranged, in an off-line set-up area set outside the component mounting line, in a component mounting system, the component preparation instruction system including: a management section that is configured to communicate with the component mounting system through a network and manages production data including information about the plurality of reel members and information about the plurality of component mounters to which the plurality of reel members is attached; a reading section that reads reel information relating to the reel members; a collating section that collates the reel information read by the reading section with the information about the plurality of reel members included in the production data; and an output section that outputs attachment position information for a matching reel member for which a collation result in the collating section indicates matching, the attachment position information including information about at least one component mounter to which the matching reel member is to be attached.

A second aspect of the present invention provides a component preparation instruction method for performing a component preparation instruction for preparing a reel member to be supplied to a component mounting line in which a plurality of component mounters is arranged, in an off-line set-up area set outside the component mounting line, in a component mounting system, the component mounting system including a management apparatus that is configured to communicate with the component mounting system through a network and manages production data including information about the plurality of reel members and information about the plurality of component mounters to which the plurality of reel members is attached, the component preparation instruction method including: reading reel information relating to the reel members; collating the read reel information with the information about the plurality of reel members included in the production data; and outputting attachment position information for a matching reel member for which a collation result indicates matching, the attachment position information including information about at least one component mounter to which the matching reel member is to be attached.

A third aspect of the present invention provides a portable terminal that is used for performing a component preparation instruction for preparing a reel member supplied to a component mounting line in which a plurality of component mounters is arranged, in an off-line set-up area set outside the component mounting line, in a component mounting system, and is configured to communicate, through a network, with a management apparatus that manages production data including information about the plurality of reel members and information about the plurality of component mounters to which the plurality of reel members is attached, the portable terminal including: a reading section that reads reel information relating to the reel members; a collating section that collates the reel information read by the reading section with the information about the plurality of reel members included in the production data; and a display section that displays attachment position information for a matching reel member for which a collation result in the collating section indicates matching, the attachment position information including information about at least one component mounter to which the matching reel member is to be attached.

According to at least one of the aspects of the present invention, it may be possible to perform automatic instruction on information matching in an off-line set-up operation of operating a component preparation operation outside a component mounting line to efficiently perform the component preparation operation.

### BRIEF DESCRIPTION OF THE DRAWINGS

FIG. 1 is a diagram illustrating a configuration of a component mounting system that includes a component preparation instruction system according to an embodiment of the present invention.

FIG. 2 is a block diagram illustrating a function of an operation area arranged in an off-line set-up area in a component preparation instruction system according to an embodiment of the present invention.

FIGS. 3A and 3B are diagrams illustrating a portable terminal used in a component preparation instruction system according to an embodiment of the present invention.

FIG. 4 is a diagram illustrating a configuration of a management apparatus in a component preparation instruction system according to an embodiment of the present invention.

FIG. 5 is a flowchart illustrating processes in a component preparation instruction method according to an embodiment of the present invention.

FIG. 6 is a diagram illustrating a display screen of a portable terminal used in a component preparation instruction system according to an embodiment of the present invention.

FIGS. 7A and 7B are diagrams illustrating a display screen of a portable terminal used in a component preparation instruction system according to an embodiment of the present invention.

FIG. 8 is a flowchart illustrating processes in a component preparation instruction method according to an embodiment of the present invention.

FIG. 9 is a flowchart illustrating processes in a component preparation instruction method according to an embodiment of the present invention.

FIG. 10 is a diagram illustrating a display screen of a portable terminal used in a component preparation instruction system according to an embodiment of the present invention.

FIG. 11 is a block diagram illustrating a function of an operation area disposed in an off-line set-up area in a component preparation instruction system according to an embodiment of the present invention.

FIG. 12 is a flowchart illustrating processes in a component preparation instruction method according to an embodiment of the present invention.

### DETAILED DESCRIPTION

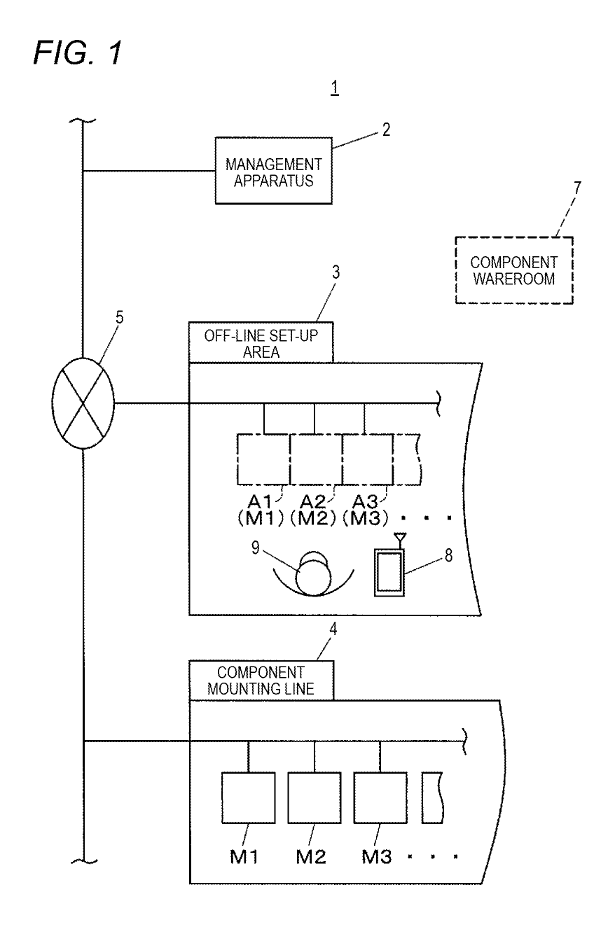

Embodiments of the present invention will be described with reference to the accompanying drawings. First, a configuration of a component mounting system 1 will be described with reference to FIG. 1. Solid lines that connect respective elements indicate communication lines. The component mounting system 1 has a function of mounting an electronic component onto a board to produce a component-mounted board, and includes a management apparatus 2, an off-line set-up area 3, and a component mounting line 4 as main elements.

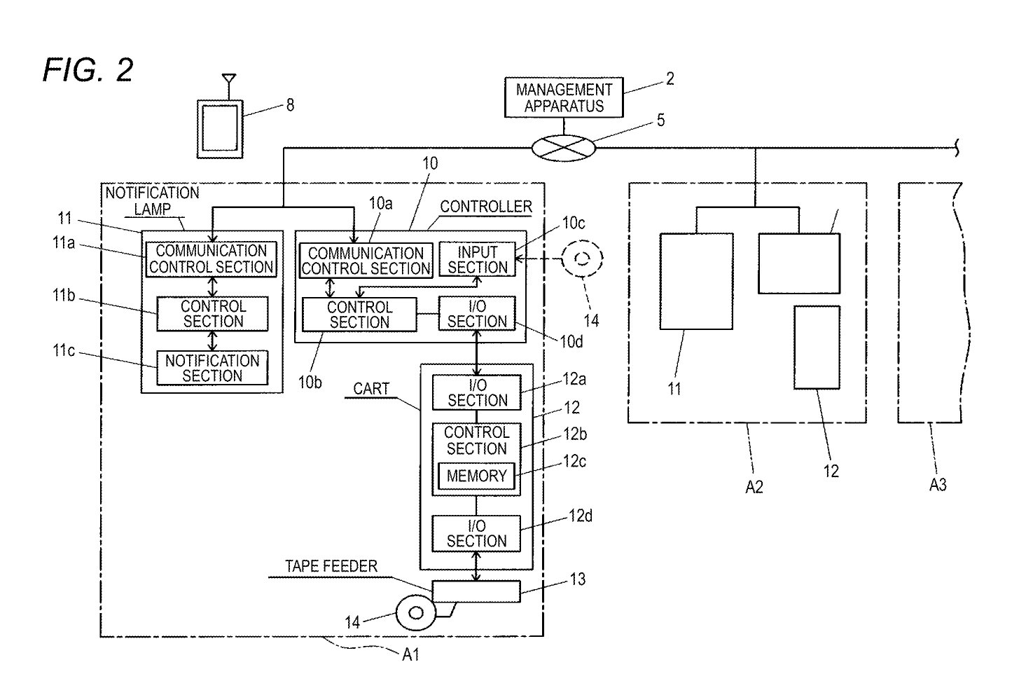

In the component mounting line 4, plural component mounters M1, M2, M3, . . . that respectively have a function of mounting an electronic component extracted from a carrier tape accommodated in a reel member 14 (see FIG. 2) in a winding state are arranged. The reel member 14 extracted from a component wareroom 7 to be supplied to the component mounting line 4 is attached to a feeder exchange cart (hereinafter, simply referred to as a “cart”) in the off-line set-up area 3 in advance, and is supplied to each component mounter of the component mounting lines in a state where a component preparation operation is performed by the so-called off-line set-up area.

The management apparatus 2 is connected to respective sections that form the component mounting system 1 through a network 5 to perform transmission or reception of data with the respective sections. The network 5 may be a wired line or a wireless line.

The management apparatus 2 is configured to store production data including information about the plural reel members 14 which are mounting targets, and information about the plural component mounters M1, M2, M3 . . . to which the plural reel members 14 are attached and stored, in order to appropriately transmit the production data to other devices. That is, the management apparatus 2 functions as a management section that manages the production data.

An operator 9 who performs an off-line set-up operation in the off-line set-up area 3 can perform data transmission or reception with the management apparatus 2 by a portable terminal 8 carried by each operator on the network 5. In the off-line set-up area 3, operation areas A1, A2, A3 . . . where the off-line set-up operation is executed by the operator 9 are arranged corresponding to the component mounters M1, M2, and M3 . . . in the component mounting line 4.

When the operator 9 executes the off-line set-up operation, reel information about the reel members 14 which are the operation targets read by the function of the portable terminal 8 is collated with the production data stored in the management apparatus 2, to specify the component mounters M1, M2, M3 . . . to which the reel member 14 is to be attached. Further, in the off-line set-up area 3, an operation of attaching a corresponding reel member to a cart carried into the operation areas A1, A2, A3 . . . corresponding to the specified component mounters M1, M2, M3 . . . is performed.

The relationship between the component mounters M1, M2, M3 . . . and the operation areas A1, A2, A3 . . . is set in advance based on an arrangement order, and the operator 9 who executes the off-line set-up operation can easily determine an operation area where the attachment operation of the reel member 14 is to be executed as the component mounter is specified.

In the above configuration, the management apparatus 2 and the portable terminal 8 form a component preparation instruction system that performs a component preparation instruction for preparing the reel member 14 which is supplied to the component mounting line 4 in the off-line set-up area 3 set outside the component mounting line 4 where the plural component mounters M1, M2, M3 . . . are arranged, in the component mounting system 1.

Hereinafter, the component preparation instruction system will be described with reference to FIGS. 2 to 5. FIG. 2 illustrates a configuration the operation areas A1, A2, A3 . . . arranged in the off-line set-up area 3 corresponding to the arrangement of the component mounters M1, M2, M3 . . . in the component mounting line 4. Since the operation areas A1, A2, A3 . . . have the same configuration, only a configuration of the operation area A1 is shown in FIG. 2, and configurations of the other operation areas are appropriately simplified.

In FIG. 2, a controller 10, a notification lamp 11, and a cart 12 are arranged in each of the operation areas A1, A2, A3 . . . . The cart 12 is a feeder exchange cart to which plural tape feeders 13 that supply components to the component mounters M1, M2, M3 . . . are attached in a batch and in a state of being combined with the reel members 14. In an off-line set-up method shown in the present embodiment, each cart 12 is carried into a predetermined one of the operation areas A1, A2, A3, . . . in the off-line set-up area 3 before being fed to the component mounting line 4, and the attachment of the reel members 14 combined with the tape feeders 13 is executed.

Configurations of the controller 10, the notification lamp 11, and the cart 12 will be described. The controller 10 and the notification lamp 11 include communication control sections 10a and 11a which are connected to the network 5, respectively, and operate the portable terminal 8 to cause the controller 10 and the notification lamp 11 to execute a predetermined function. That is, the communication control sections 10a and 11a are connected to control sections 10b and 11b, respectively. The control section 10b is connected to an input section 10c and an I/O section 10d. Here, as the control section 10b controls the input section 10c a data input process of inputting component data relating to the reel member 14 through the input section 10c is performed. As the control section 11b controls the notification section 11c, a predetermined notification is performed by turning on the notification lamp 11.

An I/O section 12a provided in the cart 12 is connected to the I/O section 10d of the controller 10. Thus, data transmission or reception is performed between the controller 10 and the control section 12b of the cart 12, and the component data relating to the reel member 14 which is input through the input section 10c is written into a memory 12c built into a control section 12b. The control section 12b is connected to the tape feeder 13 through the I/O section 12d, and data transmission or reception is performed between the control section 12b and a feeder controller built into the tape feeder 13.

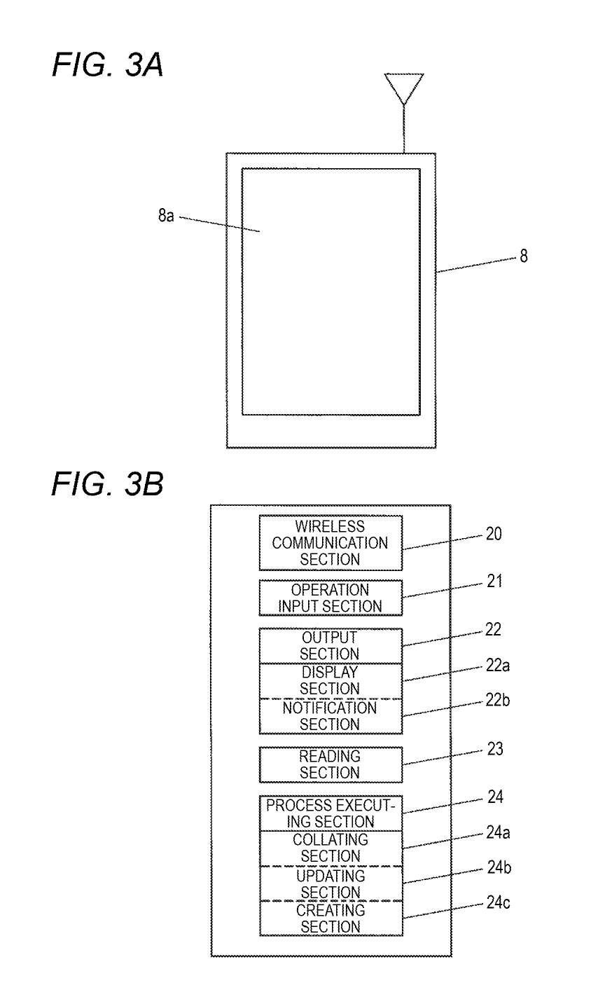

Next, a configuration and functions of the portable terminal 8 will be described with reference to FIGS. 3A and 3B. The portable terminal 8 is an electronic device that has an arithmetic processing function, a display operation function, and a communication function, for example. As shown in FIG. 3A, the portable terminal 8 has a configuration in which a display/operation screen 8a is provided in a portable case. In the display/operation screen 8a, a variety of operation buttons or input keys for instruction of execution of a variety of operations (which will be described later), display screens for commands, or processing functions may be displayed and operated.

As shown in FIG. 3B, the portable terminal 8 includes a wireless communication section 20, an operation input section 21, an output section 22, a reading section 23, and a process executing section 24. Further, the output section 22 includes a display section 22a and a notification section 22b, and the process executing section 24 includes a collating section 24a, an updating section 24b, and a creating section 24c.

The wireless communication section 20 performs a communication process for transmitting or receiving signals or data with respect to the management apparatus 2 or the controller 10, and the notification lamp 11 through the network 5. The operation input section 21 is an operational section that performs an operation input for executing a process by means of the process executing section 24, and performs a process of importing a control instruction or data that is input as the operator 9 operates the display/operation screen 8a.

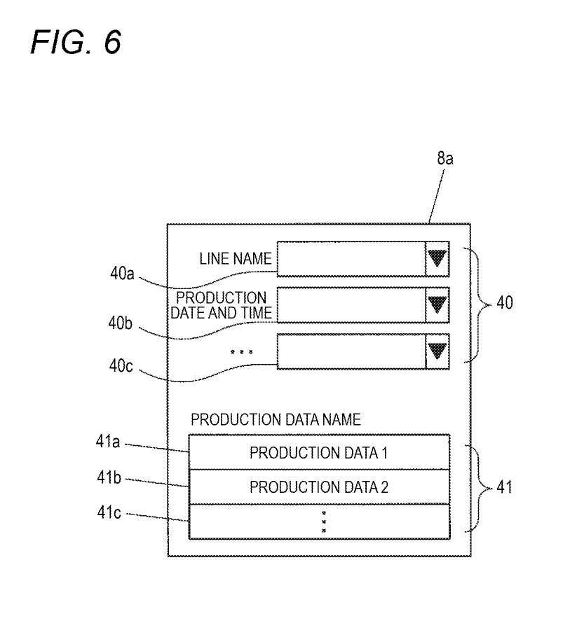

The output section 22 performs a process of outputting an operation executed by the portable terminal 8 or a determination result thereof. With respect to the reel member 14 for which a collation result in the collating section 24a indicates information matching, the output section 22 outputs attachment position information for the reel member 14 including information about at least one component mounter to which the reel member 14 is to be mounted. The display section 22a performs a process of displaying a variety of processing results executed by the process executing section 24 (which will be described later) on a display screen of the display/operation screen 8a (see FIGS. 6, 7, and 10).

The reading section 23 reads the reel information applied to the reel member 14. Here, the reel information includes a reel identification code (reel ID) assigned to the reel member 14 and a component name of an electronic component accommodated in the reel member 14, so that the reading section 23 can read any one of the reel identification code and the component name. As the reading section 23, various techniques such as a barcode reader that optically reads a first dimensional barcode and a second dimensional barcode which are the identification codes, an identifier that optically identifies a character code, or a tag reader that reads digital data from an IC tag attached to the reel member 14 may be used.

The collating section 24a collates the reel information read by the reading section 23 with the information about the plural reel members 14 included in production data 32. In the present embodiment, the reel information about each reel member 14 is read by the reading section 23 included in the portable terminal 8, and the reading result is collated with the production data 32, so that a component mounter to which the reel member 14 is to be attached is specified. Further, in the off-line set-up operation in the off-line set-up area 3, the reel member 14 is attached to the cart 12 arranged in the operation areas A1, A2, A3 . . . corresponding to the specified component mounters M1, M2, M3 . . . .

The above-described collation process is performed as the operator 9 operates the operation input section 21 which is an operating section to operate collation start and collation termination of the collating section 24a according to an instruction of the operator. That is, the collation between the reel information read by the reading section 23 and the information (component information 32a) about the plural reel members 14 included in the production data 32 is started by the collation start operation performed through the operation input section 21. Similarly, the collation between the reel information read by the reading section 23 and the information about the plural reel members 14 included in the production data 32 is terminated by the collation termination operation performed through the operation input section 21.

The updating section 24b performs a process of updating the information about the reel member 14 output from the output section 22, that is, information indicating a state of each reel member 14 into a display-completed reel member that is already displayed by the display section 22a. Thus, it is possible to check whether each reel member 14 of which the information is output is the display-completed reel member 14 of which the reel information is already read and displayed.

The creating section 24c performs a process of creating a reel member shortage list. That is, when other reel members 14 (that is, insufficient reel members 14) which are not updated into the display-completed reel members are present after the collation termination is operated by the operation input section 21 which is the operation section and the information about the reel member 14 output by the updating section 24b is updated into the display-completed reel member, the creating section 24c creates the reel member shortage list.

The created reel member shortage list is displayed on a display screen of the display/operation screen 8a by a display processing function of the display section 22a. That is, the component preparation instruction system of the present embodiment is necessary in the production data, but actually, has a configuration in which the display section 22a that displays the reel member shortage list obtained by listing up the reel members that are not checked is provided in the portable terminal 8.

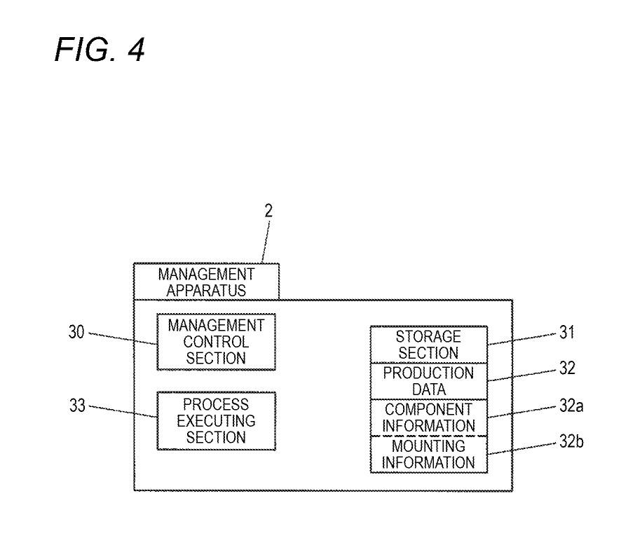

Next, a configuration of the management apparatus 2 will be described with reference to FIG. 4. The management apparatus 2 includes a management control section 30, a storage section 31, and a process executing section 33. The production data 32 is stored in the storage section 31, and the production data 32 includes component information 32a and mounting information 32b. The component information 32a indicates data relating to a component which is a mounting target, and when the component is supplied in the form of the reel member 14, the data includes the reel information assigned to the reel member 14 (reel identification code and component name). The mounting information 32b indicates data relating to a board which is a mounting target, and the data includes mounting coordinate data indicating a component mounting position on the board, sequence data indicating a mounting order, or the like.

The process executing section 33 has a function of executing a variety of operations or data processing, and can execute the same process as that of the process executing section 24 in the portable terminal 8. Accordingly, the variety of processes executed by the process executing section 24 by operating the portable terminal 8 by the operator 9 can be executed by the management apparatus 2.

The management apparatus 2 is connected to the respective devices of the portable terminal 8 or the component mounting system 1 through the network 5. Accordingly, the management apparatus 2 is configured as the management section that manages the production data 32 including information on the plural reel members 14 and information on the plural component mounters M1, M2, M3, . . . to which the plural reel members 14 are attached.

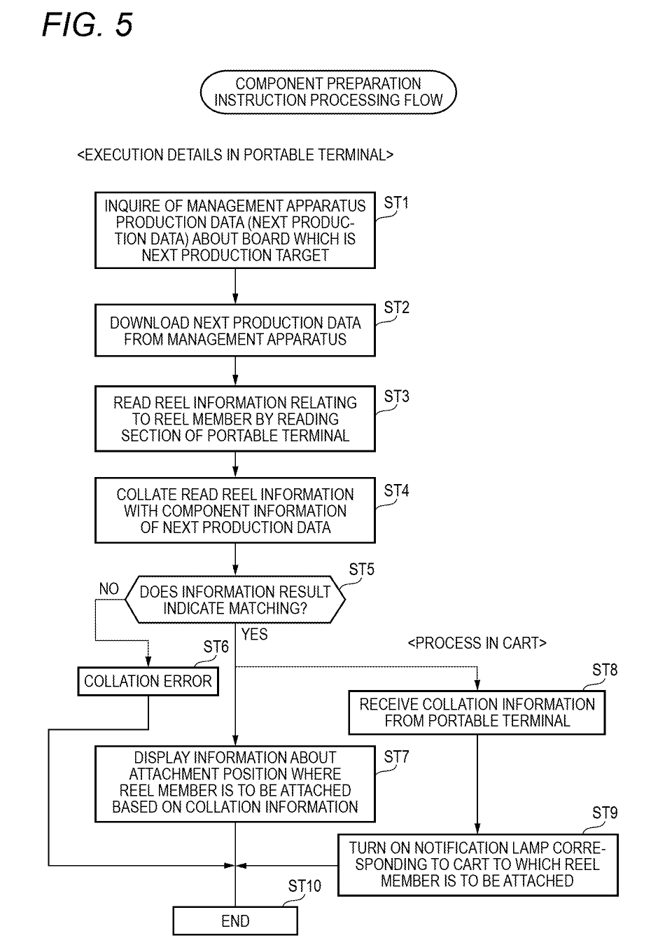

Next, a component preparation instruction method executed in the component preparation instruction system having the above-described configuration will be described with reference to a flowchart of FIG. 5. The component preparation instruction method performs a component preparation instruction for preparing the reel member 14 supplied to the component mounting line 4 in the above-described off-line set-up area 3, in the component mounting system 1. In FIG. 5, ST1 to ST5 indicate execution details by way of the portable terminal 8, and ST6 and ST7 indicate processes executed in the notification lamp 11. As a pre-operation for executing these processes, the plural reel members 14 which are operation targets are transported to the off-line set-up area 3 from the component wareroom 7, and are appropriately mounted at a predetermined position of an operation stand or the like.

In FIG. 5, first, the operator 9 who executes the operation in the off-line set-up area 3 operates the portable terminal 8 to inquire of the management apparatus 2 production data (next production data) about a board which is the next production target (ST1). In FIG. 6, an input section 40 and a display section 41 which are displayed on the display/operation screen 8a of the portable terminal 8 during its operation are provided. In the input section 40, a line name display frame 40a, a production date and time display frame 40b, and an others display frame 40c are provided. Further, a component mounting line name which is a production execution target is input to the line name display frame 40a, and a production execution date and time is input to the production date and time display frame 40b.

As the operator 9 performs an input into each item in the input section 40, corresponding production data is specified on the production management data. Production data name display frames 41a, 41b, and 41c are provided in the display section 41, and corresponding production data names are displayed in the production data name display frames 41a, 41b, and 41c. Here, as an example, production data names “production data 1”, and “production data 2” are displayed in the production data name display frames 41a and 41b, respectively.

Then, the next production data is downloaded to the portable terminal 8 from the management apparatus 2 (ST2). That is, as a corresponding production data name is touch-input from the production data names displayed in the display section 41, production data corresponding thereto is transmitted to the portable terminal 8 from the management apparatus 2. Next, in the off-line set-up area 3, the operator 9 reads reel information relating to the reel member 14 which is an operation target by the reading section 23 of the portable terminal 8 (reading process) (ST3).

In the reading process, as the reel information, a reel identification code and a component name of an electronic component are read. In this way, as the reel identification code and the production code are read in parallel, it is possible to remove an error that may occur when only one of the reel identification code and the component name is read and identified, and to accurately perform the component preparation instruction process.

Next, the reel information read in the reading process and the information about the reel member 14 included in the next production data (component information) are collated by the function of the collating section 24a (collation process) (ST4). The collation start and termination of the collation process are operated by instructions of the operator executed through the operation and input section 21 (operation process). That is, the collation between the reel information read by the reading section 23 and the information about the plural reel members 14 included in the production data 32 is started by the collation start operation and is terminated by the collation termination operation.

Further, it is determined whether the reel information read by the reading section 23 and the information about the reel member 14 match each other based on the collation result in the collation process (ST5). When the collation result in the collation process indicates matching, attachment position information including information about at least one component mounter to which the reel member 14 is to be attached is output by the portable terminal 8 (output process). The output of the attachment position information is performed as the portable terminal 8 displays information about an attachment position where the reel member 14 is to be attached on a display screen of the display/operation screen 8a based on the collation result.

When the collation result in the collation process indicates non-matching, a collation error is displayed on the display/operation screen 8a (ST6), and a unit process of the component preparation instruction is terminated (ST10). As an example of the occurrence of collation error, a case where the reel member 14 is mistakenly extracted from the component wareroom 7 may be considered.

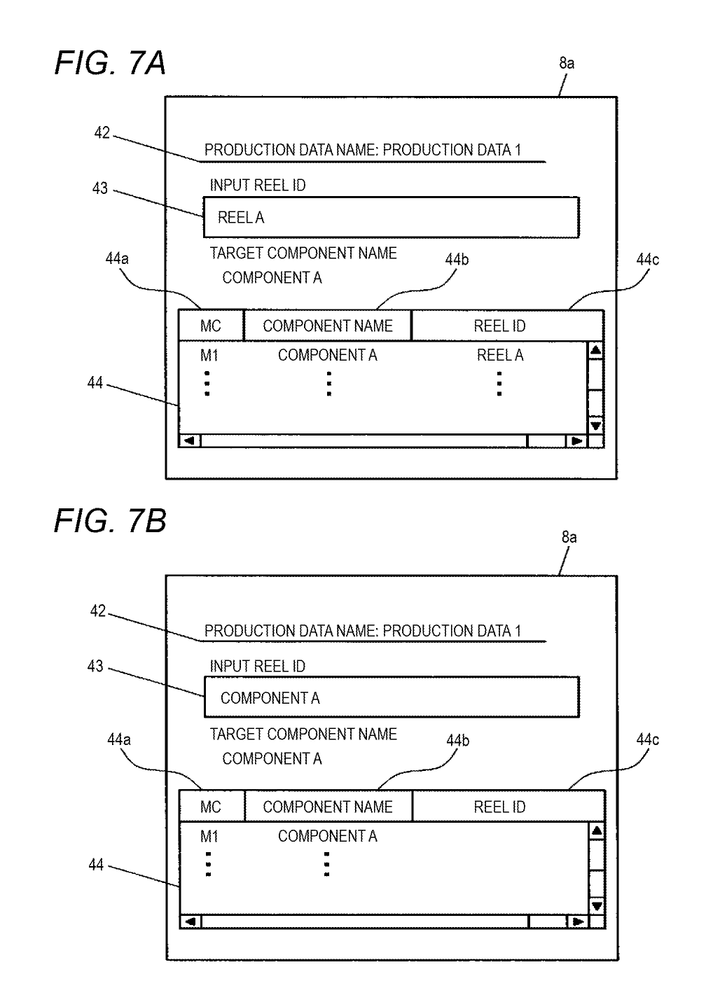

FIGS. 7A and 7B show a display/operation screen displayed on the display/operation screen 8a while the processes in ST3 to ST7 are being executed. That is, in a production data display section 42 on the display/operation screen, a downloaded production data name (here, production data 1) is displayed, and in a reel ID input frame 43, reel information read by the reading section 23 is displayed. In an example shown in FIG. 7A, a reel ID (here, reel A) which is a reel identification code for specifying the type of the reel member 14 as the reel information and a component name (reel A) corresponding to the reel ID are displayed.

In a collation result display section 44, a collation result obtained by collating the component information 32a regulated by the production data 32 with the reel ID read from the reel member 14 which is a target is shown. That is, in the collation result display section 44, an MC display section 44a for specifying a component mounter (MC) to which the reel member 14 is to be attached, a component name display section 44b indicating a component name accommodated in the reel member 14, and a reel ID display section 44c indicating the reel ID of the reel member 14 are provided. Further, details of the reel member 14 for which the collation result indicates matching, that is, a reel member 14 which is allocated as a target to be used in the production data, for which the component mounter is specified as the attachment position information, are displayed in the collation result display section 44.

In this example, a reel member 14 having a reel ID of “reel A” that accommodates a component of which the component name is “component A” is displayed as a reel member to be attached to the component mounter M1. That is, information about an attachment position where the reel member 14 is to be attached is displayed on a display screen of the portable terminal 8 based on the above-described collation information (ST7). In other words, the display section 22a has a function of displaying attachment position information including information about at least one component mounter to which the reel member 14 of which the collation result in the collating section 24a indicates matching is to be attached on the display screen of the display/operation screen 8a, and in the above-described output process, the attachment position information including the information about at least one component mounter to which the reel member 14 for which the collation result indicates matching is to be attached is displayed.

Further, if the process in the portable terminal 8 is executed in the off-line set-up area 3, the controller 10 and the notification lamp 11 receive the collation result from the portable terminal 8 through the network 5 (ST8). Then, the notification lamp 11 corresponding to the cart 12 to which the reel member 14 is to be attached is turned on based on the received collation result (ST9). Then, the component preparation instruction unit process is terminated (ST10).

That is, here, the notification section 22b has a function of performing notification for specifying the cart 12 corresponding to the attachment position information displayed on the display screen of the display/operation screen 8a, among the carts 12 that are respectively positioned in the operation areas A1, A2, A3 . . . arranged corresponding to the component mounters M1, M2, M3 . . . in the component mounting line 4 in the off-line set-up area 3, by turning on the notification lamp 11 disposed corresponding to the cart 12. That is, in the above-described output process, the notification for specifying the cart 12 that is arranged corresponding to the component mounter in the off-line set-up area 3 and corresponds to the attachment position information is performed.

When a reel identification code cannot be used as reel information about the reel member 14 which is a target, for example, as the reel identification code is not attached to the reel member, only a component name attached to the reel member 14 is read. In this case, as shown in FIG. 7B, a component name (here, component A) read instead of the reel ID is shown in the reel ID input frame 43 on the display screen. Here, only items corresponding to the MC display section 44a for specifying the component mounter (MC) to which the reel member 14 is to be attached and the component name display section 44b are displayed in the collation result display section 44.

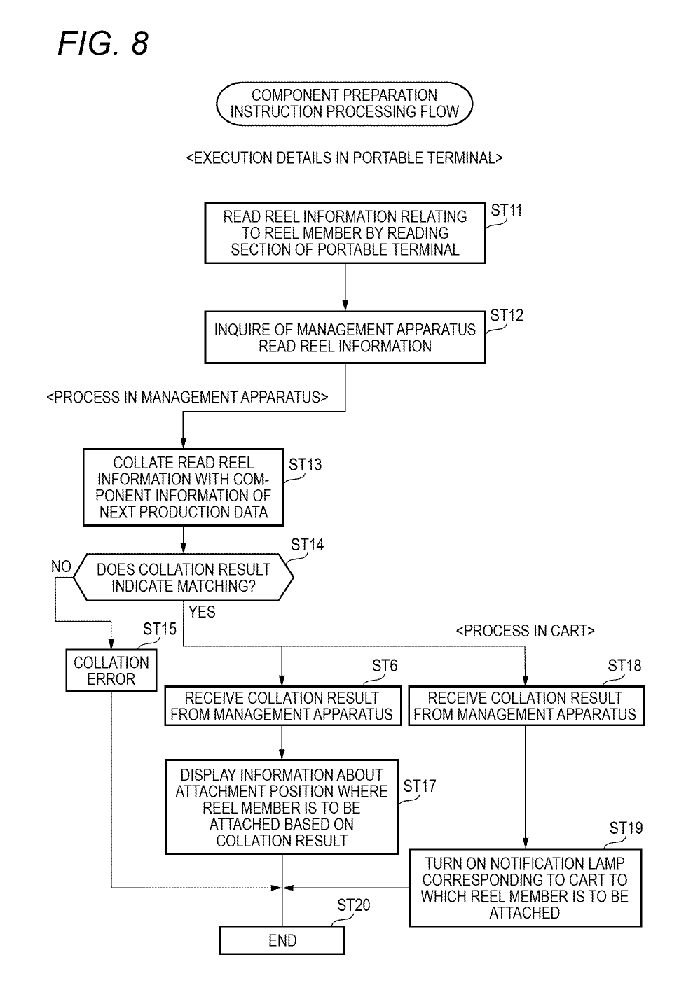

FIG. 8 shows an example in which the collation process executed by the process executing section 24 of the portable terminal 8 in the example (ST4) shown in FIG. 5 is performed by the process executing section 33 of the management apparatus 2. In FIG. 8, ST11, ST12, ST14, ST16 show execution details by means of the portable terminal 8, ST13 shows a process in the management apparatus 2, and ST18 and ST19 show processes in the cart 12.

In FIG. 8, first, the operator 9 that executes the process in the off-line set-up area 3 operates the portable terminal 8 to read reel information about the reel member 14 which is a target by the reading section 23 (ST11). Then, the operator 9 inquires of the management apparatus 2 the read reel information (ST12). Thus, the read reel information is transmitted to the management apparatus 2. Further, the management apparatus 2 that receives the reel information collates the read information with the component information 32a of the next production data stored in the storage section 31 in advance by the collation process function of the process executing section 33 (ST13).

Further, it is determined whether the collation result in the collation process indicates matching (ST14). When the collation result in the collation process indicates matching, the portable terminal 8 receives the collation result in ST13 from the management apparatus 2 (ST16), and attachment position information where the reel member 14 is to be attached is displayed on a display screen of the display/operation screen 8a of the portable terminal 8 based on the collation result (ST17). In addition, the cart 12 receives the collation result from the management apparatus 2 through the network 5 and the controller 10 (ST18), and turns on the notification lamp 11 corresponding to the cart 12 to which the reel member 14 is to be attached (ST19). Then, the component preparation instruction unit process is terminated (ST20). When the collation result in the collation process indicates non-matching in ST14, a collation error is displayed on the display/operation screen 8a (ST15), and then, the component preparation instruction unit process is terminated (ST20).

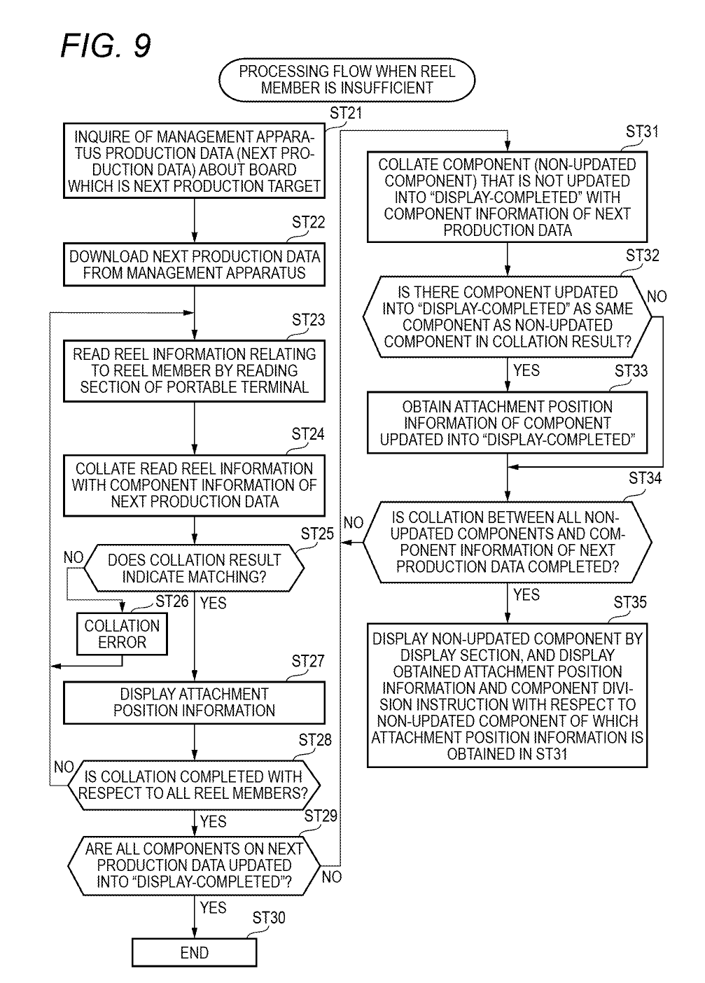

Next, a process when a reel member is insufficient will be described with reference to FIG. 9. The process refers to handling with respect to a non-updated component that is not updated into “display-completed” indicating that the presence of the reel member 14 to be used is checked as a result of the process of sequentially reading the reel information about the plural reel members 14 transported to the off-line set-up area 3 and collating the read reel information with the component information 32a of the production data 32.

In the present embodiment, as described above, the process (updating process) of updating the information indicating the state of the reel member 14, output by the output section 22, into the display-completed reel member that is already displayed in the display section 22a is executed, and thus, it is possible to determine whether the reel information is already read and displayed to check its presence with respect to each reel member 14. That is, by determining whether there is a non-updated component, it is possible to know whether there is an insufficient component.

In FIG. 9, since ST21 to ST27 are the same as ST1 to ST7 shown in FIG. 5, description thereof will not be repeated. In processes shown in FIG. 9, whenever the unit processes of ST21 to ST27 are terminated, it is determined whether the collation is completed with respect to all the reel members 14 (ST28). After the collation error is displayed in ST26, and if the collation is not completed (NO) in ST28, the procedure returns to ST23 to repeat the subsequent processes. The determination of whether the collation is completed is performed as the collating section 24a determines whether the number of times of collation corresponds to the number of pieces of component information included in the next production data that is downloaded, for example. The determination of ST26 may be determined by an operator. Further, if the collation is completed (YES), it is determined whether all components on the next production data downloaded from the management apparatus 2 are updated into “display-completed” (ST29). Here, if the updating is completed (YES), it is determined that the reel member is sufficient, and then, the procedure is terminated (ST30).

On the other hand, if the updating is not completed (NO) in ST29, a component that is not updated into “display-completed” (hereinafter, simply referred to as “non-updated component”) is collated with the component information 32a of the next production data (ST31). Then, in the above-described collation result, it is determined whether there is a component updated into “display-completed” as the same component as the non-updated component (ST32). Here, if there is a component updated into “display-completed” (YES), attachment position information of the component updated into “display-completed” is obtained (ST33).

Then, it is determined whether the collation between all the non-updated components and the component information 32a of the next production data is completed (ST34). This is similarly applied to a case where it is determined in ST32 that there is no component updated into “display-completed” (NO). Here, the collation is not completed (NO), the procedure returns to ST31 to repeat the subsequent processes. Further, if the collation is completed (YES) in ST34, the non-updated component is displayed on the display screen of the display/operation screen 8a by the display section 22a, and with respect to the non-updated component of which the attachment position information is obtained in ST33, the obtained attachment position information and a component division instruction are displayed (ST35).

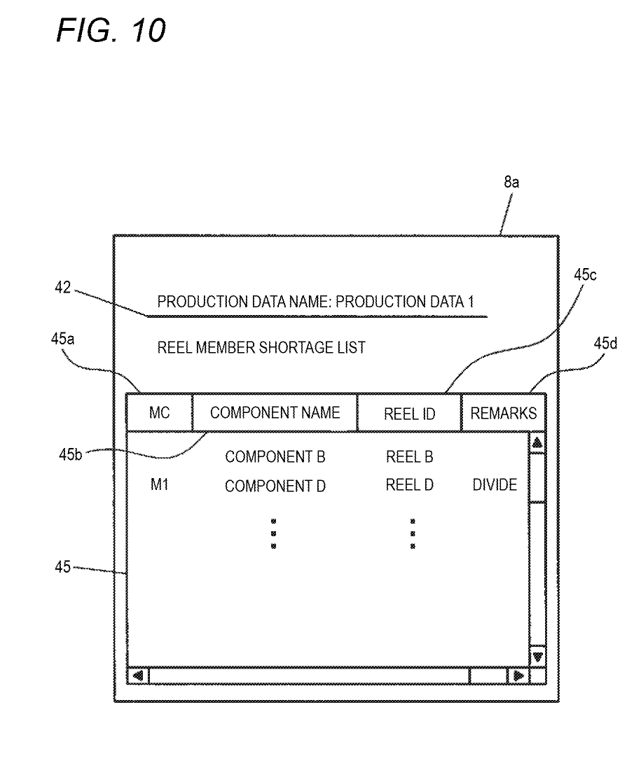

FIG. 10 shows an example of a display screen displayed on the display/operation screen 8a in ST35. Here, a list of the reel members 14 which are insufficient when the production data displayed in the production data display section 42 (here, production data 1) is a target, that is, a reel member shortage list is created (creation process), and is displayed in a shortage list display section 45 on a display screen of the display/operation screen 8a. In this example, a case where two types of reel members 14 of (component-B, reel ID-B) and (component-D, reel ID-D) which are respectively displayed in an MC display section 45b and a reel ID display section 45c are insufficient is shown.

The creation of the above-described reel member shortage list is performed by the creating section 24c when there is another reel member that is not updated into the displayed reel member after the collation termination is operated by the operation of the operation input section 21 (operating section) and the information about the output reel member 14 is updated into the display-completed reel member by the updating section 24b. In this way, as the reel member shortage list is automatically created and output, it is possible to rapidly and efficiently perform supplementary preparations of insufficient components.

Here, with respect to the reel member 14 of (component-D, reel ID-D), attachment position information (here, component mounter M2) is displayed in the MC display section 45a, and “division” is displayed in a remarks display section 45d. The display represents a component division instruction for indicating that it is necessary to create the plural reel members 14 that supply the same component by dividing a carrier tape accommodated in the reel member 14 into plural pieces to be wound and accommodated in the plural reel members 14.

That is, when there are plural reel members 14 for which the collation result indicates matching in the collation process, and when there is another reel member 14 that is not updated after information about one reel member 14 is updated by the updating section 24b, the instruction for dividing the carrier tape accommodated in the output reel member 14 into plural reel members 14 is displayed.

In this way, as the component division instruction is automatically performed, even when the number of the reel members 14 does not satisfy a necessary number with respect to the same type component, it is possible to temporarily supply the reel member 14 created by the division to the component mounter where the reel member 14 which is a corresponding component is insufficient, to thereby prevent device operation stoppage due to a component shortage. Here, by displaying the information about the attachment position where the insufficient reel member 14 is attached and the component division instruction, it is possible to easily specify a target of the reel division operation.

Further, the created reel member shortage list may be transmitted through the network 5 to the portable terminal 8 of an operator (not shown) who manages delivery of a component to the off-line set-up area 3 from the component wareroom 7. The delivery managing operator who receives the reel member shortage list through the portable terminal 8 may deliver a reel member for which a division instruction is not issued from the component wareroom 7 based on the reel member shortage list.

Further, the created reel member shortage list may be transmitted to the management apparatus 2 through the network 5. The management apparatus 2 collates the production data 32 stored in the storage section 31, for which the production is being executed, with the received reel member shortage list. As a result of collation, when there is a reel member of the reel member shortage list in the production data 32, the management apparatus 2 displays the position of a corresponding component mounter (component mounting line name, equipment name, feeder number or the like) on a display screen of the portable terminal 8 of the operator 9. The operator 9 may divide a corresponding reel member based on the displayed component mounter to perform preparation for an insufficient reel member.

Here, the operator 9 may register information about the operator 9 (operator ID, operator name, off-line set-up area where the operator performs operation, or the like) in the portable terminal 8 carried by the operator 9, and a reel member shortage list to which the information about the operator is added may be created. As the information about the operator 9 is added to the reel member shortage list, the delivery managing operator who receives the reel member shortage list through the portable terminal 8 may transmit the delivered reel member to the operator 9 who creates the reel member shortage list.

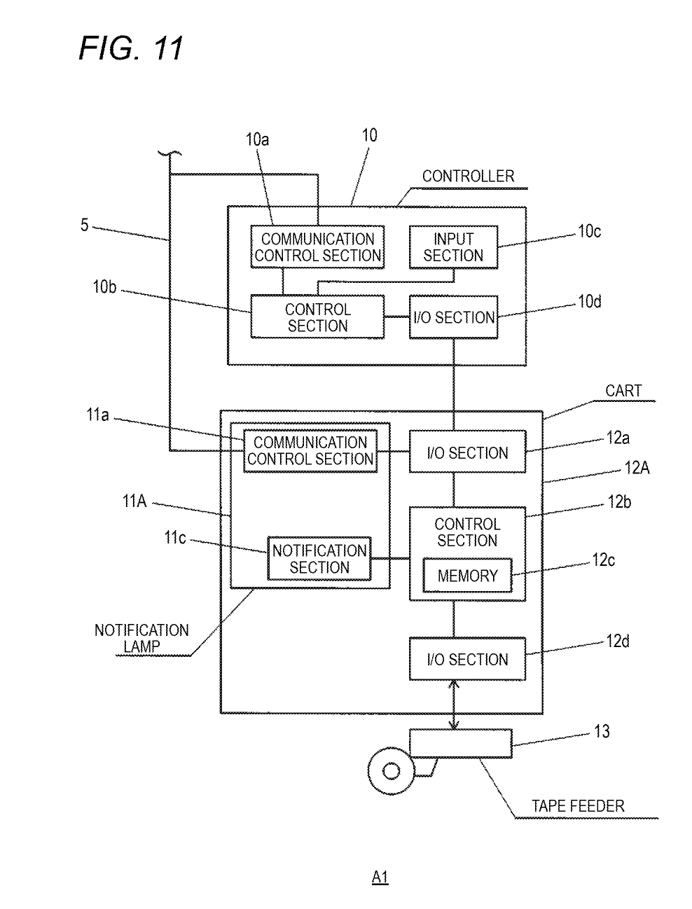

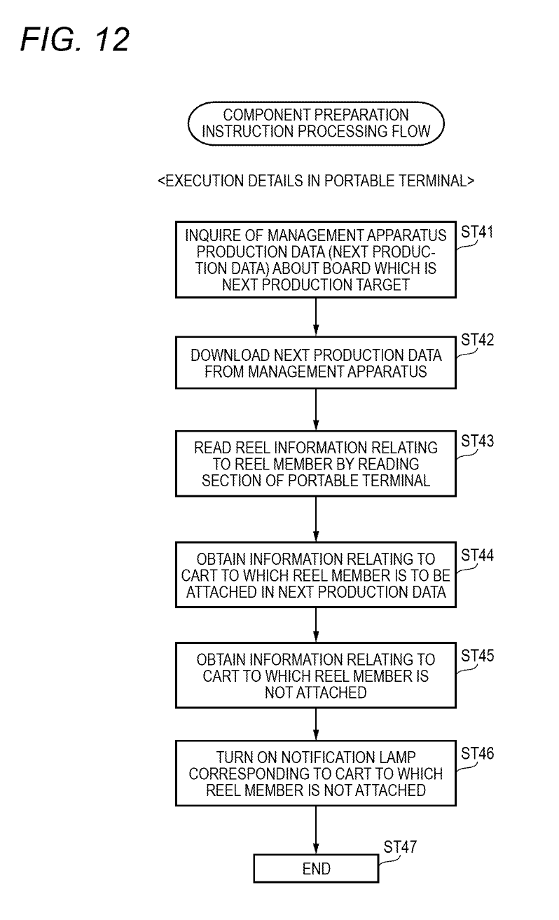

In the above-described example, an example in which the notification lamp 11 that is turned on for specifying the cart 12 corresponding to the attachment position information in the off-line set-up area 3 and the cart 12 are individually arranged is shown, but as shown in FIG. 11, a configuration in which a notification lamp 11A and a cart 12A are integrated may be used. In this configuration, a component preparation instruction process as shown in FIG. 12 may be performed.

In FIG. 12, first, the operator 9 who executes an operation in the off-line set-up area 3 operates the portable terminal 8 to inquire of the management apparatus 2 production data (next production data) of a board which is the next production target (ST41). Then, the next production data is downloaded from the management apparatus 2 to the portable terminal 8 (ST42). In the off-line set-up area 3, the operator 9 reads reel information relating to a reel member 14 by the reading section 23 of the portable terminal 8 (ST43).

Thereafter, information about the I/O section 12a where the reel member 14 is to be attached in the next production data is obtained (ST44), and then, information about the cart 12A to which the reel member 14 is not attached is obtained (ST45). Further, the notification lamp 11A corresponding to the cart 12A to which the reel member 14 is not attached is turned on (ST46), and the component preparation instruction process is terminated (ST47). In this example, the operator can specify only the cart 12A where component supply is necessary, to thereby make it possible to enhance efficiency of the component preparation operation.

As described above, in the component preparation instruction system, the component preparation instruction method, and the portable terminal shown in the present embodiment, the component preparation instruction system that performs instruction on information matching in the off-line set-up operation performed outside the component mounting line is configured by the management apparatus 2 that manages production data including information about the reel member 14 and information about plural component mounters to which the reel member 14 is to be attached, and the portable terminal 8 that includes the reading section 23 that reads reel information relating to the reel member 14, the collating section 24a that collates the read reel information with the information about the plural reel members 14 included in the production data, and the output section 22 that outputs information about an attachment position where the reel member 14 for which the collation result indicates matching is to be attached. Thus, during the off-line set-up operation, it is possible to perform automatic instruction on information matching, and to accurately perform the component preparation operation with high accuracy without errors.

The management apparatus 2 may associate production data 32 in the storage section 31 with operators 9 who manage the operation areas A1, A2, A3 . . . for storage, and when each operator 9 inquires of the management apparatus 2 the next production data, the production data 32 relating to the operation areas A1, A2, A3 . . . managed by the operator who makes the inquiry may be downloaded. Thus, even in large sized equipment with plural mounting lines, the operator 9 who performs the off-line set-up operation in the off-line set-up area 3 can receive the next production data relating to the operation areas A1, A2, A3 . . . managed by the operator 9, to thereby make it possible to accurately perform the component preparation operation with high accuracy without errors.

According to the component preparation instruction system, the component preparation instruction method, and the portable terminal of the present invention, it is possible to automatically instruct information matching in an off-line set-up operation for performing a component preparation operation outside a component mounting line to efficiently perform the component preparation operation, which is useful in a component mounting field in which a component is supplied by a reel member to be mounted onto a board.

What is claimed is:

1. A component preparation instruction system that performs a component preparation instruction for preparing a reel member to be supplied to a component mounting line in which a plurality of component mounters is arranged, in an off-line set-up area set outside the component mounting line, in a component mounting system, the component preparation instruction system comprising:
a management section that is configured to communicate with the component mounting system through a network and manages production data including information about the plurality of reel members and information about the plurality of component mounters to which the plurality of reel members is attached;
a reading section that reads reel information relating to the reel members;
a collating section that collates the reel information read by the reading section with the information about the plurality of reel members included in the production data; and
an output section that outputs attachment position information for a matching reel member for which a collation result in the collating section indicates matching, the attachment position information including information about at least one component mounter to which the matching reel member is to be attached.

2. The component preparation instruction system according to claim 1, wherein the reel information includes a reel identification code assigned to each reel member and a component name of an electronic component accommodated in the reel member, and the reading section reads the reel identification code and the component name of the electronic component.

3. The component preparation instruction system according to claim 1, wherein the output section includes
a display section that displays the attachment position information including the information about at least one component mounter to which the matching reel member is to be attached, and
a notification section that performs notification for specifying a feeder exchange cart corresponding to the attachment position information, which is disposed corresponding to the component mounter in the off-line set-up area.

4. The component preparation instruction system according to claim 3, further comprising:
an updating section that updates the information about the reel member for which the attachment position information is output into a display-completed reel member for which the attachment position information is already displayed by the display section,
wherein when there is a plurality of matching reel members for which the collation result in the collating section indicates matching, and when there is another reel member of which information is not updated after information about one reel member is updated by the updating section, the display section displays an instruction for dividing a carrier tape accommodated in the reel member for which the attachment position information is output into a plurality of reel members.

5. The component preparation instruction system according to claim 3, further comprising:
an operating section that operates a collation start and a collation termination of the collating section according to an operator's instruction,
wherein the operating section starts the collation between the reel information read by the reading section and the information about the plurality of reel members included in the production data according to a collation start operation, and terminates the collation between the reel information read by the reading section and the information about the plurality of reel members included in the production data according to a collation termination operation.

6. The component preparation instruction system according to claim 5, further comprising:
a creating section that creates a reel member shortage list,
wherein when there is another reel member that is not updated into the display-completed reel member after the collation termination is operated by the operating section and the updating section updates the information about the reel member for which the attachment position information is output into the display-completed reel member, the creating section creates the reel member shortage list.

7. The component preparation instruction system according to claim 6, wherein the display section displays the created reel member shortage list.

8. A component preparation instruction method for performing a component preparation instruction for preparing a reel member to be supplied to a component mounting line in which a plurality of component mounters is arranged, in an off-line set-up area set outside the component mounting line, in a component mounting system,
the component mounting system including a management apparatus that is configured to communicate with the component mounting system through a network and manages production data including information about the plurality of reel members and information about the plurality of component mounters to which the plurality of reel members is attached,
the component preparation instruction method comprising:
reading reel information relating to the reel members;
collating the read reel information with the information about the plurality of reel members included in the production data; and
outputting attachment position information for a matching reel member for which a collation result indicates matching, the attachment position information including information about at least one component mounter to which the matching reel member is to be attached.

9. The component preparation instruction method according to claim 8, further comprising:
displaying the attachment position information including the information about at least one component mounter to which the matching reel member is to be attached, and
performing notification for specifying a feeder exchange cart corresponding to the attachment position information, which is disposed corresponding to the component mounter in the off-line set-up area.

10. The component preparation instruction method according to claim 8, wherein the reel information includes a reel identification code assigned to each reel member and a component name of an electronic component accommodated in the reel member, and the reel identification code and the component name of the electronic component are read in the reading.

11. The component preparation instruction method according to claim 9, further comprising:
updating the information about the reel member for which the attachment position information is output into a display-completed reel member,
displaying, when there is a plurality of matching reel members for which the collation result indicates matching, and when there is another reel member of which information is not updated after information about one reel member is updated in the updating, an instruction for dividing a carrier tape accommodated in the reel member for which the attachment position information is output into a plurality of reel members.

12. The component preparation instruction method according to claim 9, wherein the collation between the reel information read in the reading and the information about the plurality of reel members included in the production data is started according to a collation start operation by an operator's instruction, and the collation between the reel information read in the reading and the information about the plurality of reel members included in the production data is terminated according to a collation termination operation by an operator's instruction.

13. The component preparation instruction method according to claim 12, further comprising:
creating a reel member shortage list when there is another reel member that is not updated into the display-completed reel member after the collation termination is operated in the operating and the information about the reel member for which the attachment position information is output is updated into the display-completed reel member in the updating.

14. The component preparation instruction method according to claim 13, further comprising:
displaying the created reel member shortage list by a display section.

15. A portable terminal that is used for performing a component preparation instruction for preparing a reel member supplied to a component mounting line in which a plurality of component mounters is arranged, in an off-line set-up area set outside the component mounting line, in a component mounting system, and is configured to communicate, through a network, with a management apparatus that manages production data including information about the plurality of reel members and information about the plurality of component mounters to which the plurality of reel members is attached, the portable terminal comprising:
a reading section that reads reel information relating to the reel members;
a collating section that collates the reel information read by the reading section with the information about the plurality of reel members included in the production data; and
a display section that displays attachment position information for a matching reel member for which a collation result in the collating section indicates matching, the attachment position information including information about at least one component mounter to which the matching reel member is to be attached.

16. The portable terminal according to claim 15, wherein the reel information includes a reel identification code assigned to each reel member and a component name of an electronic component accommodated in the reel member, and the reading section reads the reel identification code and the component name of the electronic component.

17. The portable terminal according to claim 15, further comprising:
an updating section that updates the information about the reel member for which the attachment position information is output into a display-completed reel member for which the attachment position information is already displayed by the display section,
wherein when there is a plurality of matching reel members for which the collation result in the collating section indicates matching, and when there is another reel member of which information is not updated after information about one reel member is updated by the updating section, the display section displays an instruction for dividing a carrier tape accommodated in the reel member for which the attachment position information is output into a plurality of reel members.

18. The portable terminal according to claim 15, further comprising:
an operating section that operates a collation start and a collation termination of the collating section according to an operator's instruction,
wherein the operating section starts the collation between the reel information read by the reading section and the information about the plurality of reel members included in the production data according to a collation start operation, and terminates the collation between the reel information read by the reading section and the information about the plurality of reel members included in the production data according to a collation termination operation.

19. The portable terminal according to claim 15, further comprising:
a creating section that creates a reel member shortage list,
wherein when there is another reel member that is not updated into the display-completed reel member after the collation termination is operated by the operating section and the updating section updates the information about the reel member for which the attachment position information is output into the display-completed reel member, the creating section creates the reel member shortage list.

20. The portable terminal according to claim 19, wherein the display section displays the created reel member shortage list.
